(19) United States
(12) Patent Application Publication
(10) Pub. No.: US 2012/0104485 A1
(43) Pub. Date: May 3, 2012

(54) Nonvolatile Memory Devices And Methods Of Manufacturing The Same

(75) Inventors: Junkyu Yang, Seoul (KR); HongSuk Kim, Yongin-si (KR); Kihyun Hwang, Seongnam-si (KR); Jaeyoung Ahn, Seongnam-si (KR); Guk-Hyon Yon, Hwaseong-si (KR)

(73) Assignee: SAMSUNG ELECTRONICS CO., LTD., Suwon-si (KR)

(21) Appl. No.: 13/281,784

(22) Filed: Oct. 26, 2011

(30) Foreign Application Priority Data
Oct. 27, 2010 (KR) 10-2010-0105304

(51) Int. Cl. H01L 29/792

(52) U.S. Cl. 257/324; 257/E29.309

(57) ABSTRACT

A method of manufacturing a nonvolatile memory device includes forming a tunnel dielectric layer, a charge storage layer, and a hard mask layer on a substrate in sequential order. Active portions are defined by forming trenches in the substrate. A tunnel dielectric pattern, a preliminary charge storage pattern, and a hard mask pattern are formed on each of the active portions in sequential order by sequentially patterning the hard mask layer, the charge storage layer, the tunnel dielectric layer, and the substrate. A capping pattern is formed covering an upper surface of the trenches such that a first void remains in a lower portion of the trenches, the capping pattern including etch particles formed by etching the hard mask pattern through a sputtering etch process.

### CROSS-REFERENCE TO RELATED APPLICATIONS

This U.S. non-provisional patent application claims priority under 35 U.S.C. §119 to Korean Patent Application No. 10-2010-0105304, filed on Oct. 27, 2010, the entire contents of which are hereby incorporated by reference.

### BACKGROUND

1. Field

The present inventive concepts herein relate to nonvolatile memory devices and/or methods of manufacturing the same, and more particularly, to nonvolatile memory devices including voids and/or methods of manufacturing the same.

2. Description of the Related Art

As various electronic devices use a semiconductor in almost all industry fields such as a car and a ship, a status that the semiconductor industry has in a modern industrial structure becomes higher. As a semiconductor device is utilized in various industrial fields and becomes an important factor in determining quality of electronic devices, cars, and ships, a demand for a semiconductor device having excellent characteristics becomes increased. In order to meet the demand, semiconductor technologies for realizing high integration, low power consumption and/or high speed of a semiconductor device are currently in progress.

Especially, since the degree of integration in a nonvolatile memory device is mainly determined by an area that a unit memory cell occupies, a pattern miniaturization as a method for a high integration of a nonvolatile memory device is continuously progressed. However, due to the pattern miniaturization, reliability and electrical characteristics of a nonvolatile memory device are deteriorated. Accordingly, various studies for increasing the degree of integration in a nonvolatile memory device and improving the reliability and electrical characteristics are conducted recently.

### SUMMARY

The present inventive concepts provide a nonvolatile memory device with improved reliability and electrical characteristics and/or a method of manufacturing the same. The present inventive concepts also provide a nonvolatile memory device optimized for high integration and/or a method of manufacturing the same.

According to an example embodiment of the inventive concepts, a method of manufacturing a nonvolatile memory device includes forming a tunnel dielectric layer, a charge storage layer, and a hard mask layer on a substrate in sequential order. Active portions are defined by forming trenches in the substrate. A tunnel dielectric pattern, a preliminary charge storage pattern, and a hard mask pattern are formed on each of the active portions in sequential order by sequentially patterning the hard mask layer, the charge storage layer, the tunnel dielectric layer, and the substrate. A capping pattern is formed covering an upper portion of the trenches such that a void remains in a lower portion of the trenches, the capping pattern including etch particles formed by etching the hard mask pattern through a sputtering etch process.

The preliminary charge storage pattern may include a plurality of preliminary charge storage patterns. Forming the capping pattern may further include forming laterally extending protruding patterns by re-depositing the etch particles on sidewalls of the plurality of preliminary charge storage patterns. Forming the capping pattern may further include forming an insulation pattern filling a space between pairs of the protruding patterns disposed on the upper portion of the trenches.

Forming the insulation pattern may include forming a liner insulation layer that conformally covers surfaces of the protruding patterns. A bulk insulation layer may be formed on the liner insulation layer, and the bulk insulation layer and the liner insulation layer may be planarized until an upper surface of the preliminary charge storage pattern is exposed.

A blocking dielectric layer and a control gate layer may be formed in sequential order on the substrate having the capping pattern. A charge storage pattern, blocking dielectric pattern, and control gate electrode may be formed in sequential order by sequentially patterning the control gate layer, the blocking dielectric layer, and the preliminary charge storage pattern.

The control gate electrode may include a plurality of control gate electrodes. An interlayer insulation layer may be formed on the plurality of control gate electrodes, the interlayer insulation layer including a second void formed therein between the plurality of control gate electrodes. The first void and the second void may be separated from each other by the capping pattern. A lower portion of the second void may be disposed at a lower level than an upper surface of the charge storage pattern.

Before the forming the interlayer insulation layer, the method may further comprise etching the capping pattern between the control gate electrodes such that the first and second voids are connected to each other. The capping pattern between the control gate electrodes and the preliminary storage pattern may be simultaneously etched by an etch process that forms the charge storage pattern.

According to another example embodiment of the inventive concepts, a nonvolatile memory device comprises active portions defined by a trench in a substrate, the active portions extending parallel to a first direction. Charge storage patterns are disposed on the active portions, the charge storage patterns having first sidewalls parallel to the first direction and second sidewalls parallel to a second direction intersecting the first direction. A tunnel dielectric pattern is interposed between the active portions and the charge storage pattern. A capping pattern is disposed between the first sidewalls of the charge storage patterns, and covers an upper portion of the trench to define a first void in a lower portion of the trench. The capping pattern includes laterally extending protruding patterns re-deposited by a sputtering etch process. A control gate electrode is disposed on the charge storage patterns. Blocking dielectric patterns are interposed between the charge storage patterns and the control gate electrode.

The control gate electrode may be a plurality of control gate electrodes laterally extending in the second direction. The charge storage pattern may be a plurality of charge storage patterns two-dimensionally arranged along rows and columns. Each of the control gate electrodes may be disposed on an upper surface of the charge storage patterns in each of the columns parallel to the second direction.

The nonvolatile memory device may further comprise an interlayer insulation layer on the plurality of control gate electrodes. A second void may be defined between the plurality of control gate electrodes. The first void and the second void may be connected to each other. The first void and the second void may also be separated from each other by the capping pattern.

According to yet another example embodiment of the inventive concepts, a method of manufacturing a nonvolatile memory device comprises defining active portions by forming trenches in a substrate using a hard mask pattern. A capping pattern is formed covering an upper portion of the trenches such that a void remains in a lower portion of the trenches, the capping pattern including etch particles formed by etching the hard mask pattern through a sputtering etch process.

A tunnel dielectric layer, a charge storage layer, and a hard mask layer may be formed on the substrate in sequential order. A tunnel dielectric pattern, a preliminary charge storage pattern, and the hard mask pattern may be formed on each of the active portions in sequential order by sequentially patterning the hard mask layer, the charge storage layer, the tunnel dielectric layer, and the substrate.

A blocking dielectric layer and a control gate layer may be formed in sequential order on the substrate having the capping pattern. A charge storage pattern, blocking dielectric pattern, and control gate electrode may be formed in sequential order by sequentially patterning the control gate layer, the blocking dielectric layer, and the preliminary charge storage pattern.

The control gate electrode may include a plurality of control gate electrodes. An interlayer insulation layer may be formed on the plurality of control gate electrodes. A second void may be defined between the plurality of control gate electrodes. A lower portion of the second void may be disposed at a lower level than an upper surface of the charge storage pattern.

According to still another example embodiment of the inventive concepts, a nonvolatile memory device comprises active portions defined by a trench in a substrate, the active portions extending parallel to a first direction. Charge storage patterns are disposed on the active portions, the charge storage patterns having first sidewalls parallel to the first direction and second sidewalls parallel to a second direction intersecting the first direction. A capping pattern is disposed between the first sidewalls of the charge storage patterns and covering an upper portion of the trench to define a first void in a lower portion of the trench, the capping pattern including laterally extending protruding patterns.

A tunnel dielectric pattern may be interposed between the active portions and the charge storage pattern. A plurality of control gate electrodes may be disposed on upper surfaces of the charge storage patterns. Blocking dielectric patterns may be interposed between the charge storage patterns and the plurality of control gate electrodes, the plurality of control gate electrodes laterally extending in the second direction.

An interlayer insulation layer may be formed on the plurality of control gate electrodes. A second void may be defined between the plurality of control gate electrodes. The first void and the second void may be connected to each other. The first void and the second void may also be separated from each other by the capping pattern.

### BRIEF DESCRIPTION OF THE DRAWINGS

The accompanying drawings are included to provide a further understanding of the inventive concepts, and are incorporated in and constitute a part of this specification. The drawings illustrate example embodiments of the inventive concepts and, together with the description, serve to explain principles of the inventive concepts. In the drawings:

FIGS. 1 through 10 are perspective views illustrating a method of manufacturing a nonvolatile memory device according to an example embodiment of the inventive concepts;

FIGS. 11A and 11B are sectional views taken along the line I-I′ of FIG. 10;

FIG. 12A is a perspective view illustrating a nonvolatile memory device according to an example embodiment of the inventive concepts;

FIG. 12B is a perspective view taken along the line II-IF of FIG. 12A;

FIG. 13A is a perspective view illustrating a nonvolatile memory device according to another example embodiment of the inventive concepts;

FIGS. 13B and 13C are perspective views taken along the line of FIG. 13A;

FIG. 14 is a block diagram illustrating one example of a memory system including a nonvolatile memory device according to example embodiments of the inventive concepts; and

FIG. 15 is a block diagram illustrating one example of a memory card including a nonvolatile memory device according to example embodiments of the inventive concepts.

### DETAILED DESCRIPTION OF EXAMPLE EMBODIMENTS

Advantages and features of the inventive concepts, and implementation methods thereof will be clarified through the following example embodiments described with reference to the accompanying drawings. Example embodiments of the inventive concepts will be described below in more detail with reference to the accompanying drawings. The inventive concepts may, however, be embodied in different forms and should not be construed as limited to example embodiments set forth herein. Rather, these example embodiments are provided so that this disclosure will be thorough and complete, and will fully convey the scope of the inventive concepts to those skilled in the art.

The meaning of “include,” “comprise,” “including,” or “comprising,” specifies a property, a region, a fixed number, a step, a process, an element and/or a component but does not exclude other properties, regions, fixed numbers, steps, processes, elements and/or components. It will be understood that when an element such as a layer, film, region, or substrate is referred to as being “on” another element, it can be directly on the other element or intervening elements may also be present.

Additionally, the example embodiment in the detailed description will be described with sectional views as ideal example views of the inventive concepts. In the figures, the dimensions of layers and regions are exaggerated for clarity of illustration. Accordingly, shapes of the exemplary views may be modified according to manufacturing techniques and/or allowable errors. Therefore, the example embodiments of the inventive concepts are not limited to the specific shape illustrated in the exemplary views, but may include other shapes that may be created according to manufacturing processes. Areas exemplified in the drawings have general properties, and are used to illustrate a specific shape of a semiconductor package region. Thus, this should not be construed as limited to the scope of the inventive concepts.

Also, though terms like a first and a second are used to describe various members, components, regions, layers, and/or portions in various example embodiments of the inventive concepts, the members, components, regions, layers, and/or portions are not limited to these terms. Like reference numerals refer to like elements throughout.

Method of Manufacturing Nonvolatile Memory Device

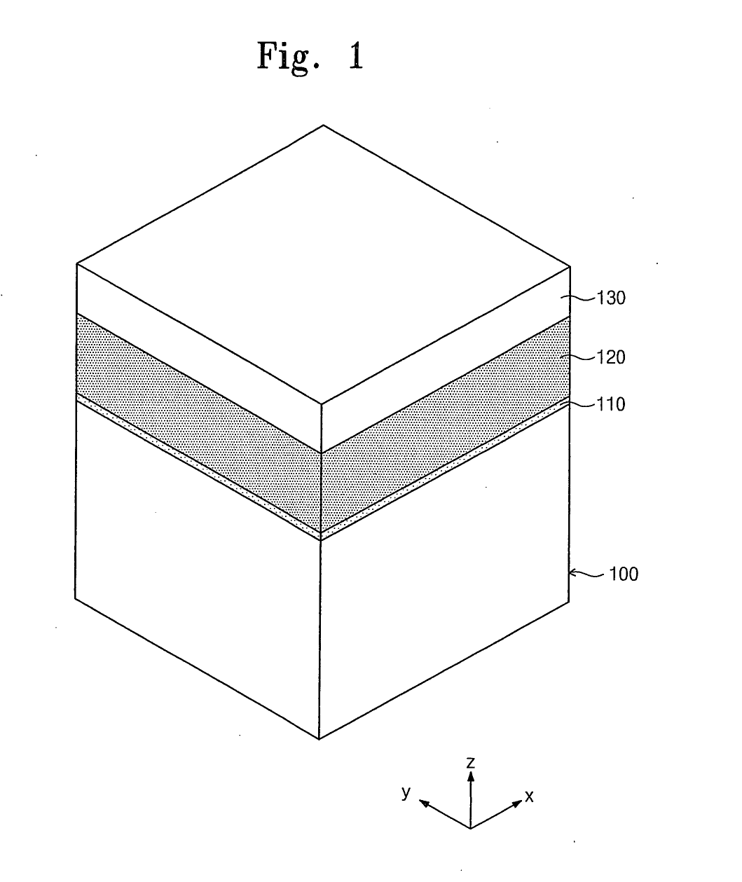

Hereinafter, a method of manufacturing a nonvolatile memory device according to example embodiments of the inventive concepts will be described with reference to the drawings. FIGS. 1 through 8 are perspective views illustrating a method of manufacturing a nonvolatile memory device according to an example embodiment of the inventive concepts.

Referring to FIG. 1, a tunnel dielectric layer 110, a charge storage layer 120, and a first hard mask layer 130 are sequentially formed on a substrate 100. The substrate 100 may include a semiconductor material. For example, the substrate 100 may include at least one of silicon or germanium.

The tunnel dielectric layer 110 may be single-layered or multi-layered. The tunnel dielectric layer 110 may be formed through one of a Chemical Vapor Deposition (CVD) process, a Physical Vapor Deposition (PVD) process, an Atomic Layer Deposition (ALD) process, or a thermal oxidation process. The thermal oxidation process may use a process gas including at least one of oxygen, nitrogen dioxide, nitric oxide, or hydrogen peroxide. The tunnel dielectric layer 110 may include at least one of an oxide layer (e.g., a thermal oxide layer and/or a CVD-oxide layer), a nitride layer, a metal oxide layer and/or a nitride layer.

The charge storage layer 120 may include doped polysilicon or undoped polysilicon. The charge storage layer 120 may include a charge trap site for storing charges. For example, the charge storage layer 120 may include at least one of silicon nitride, metal nitride, metal oxide, metal silicon oxide, metal silicon oxide, or nano dots. The charge storage layer 120 may be formed through at least one of CVD, PVD, and ALD.

A first hard mask layer 130 may be formed on the charge storage layer 120. The first hard mask layer 130 may be formed through at least one of CVD and ALD. The first hard mask layer 130 may include at least one of oxide, nitride, or oxide nitride.

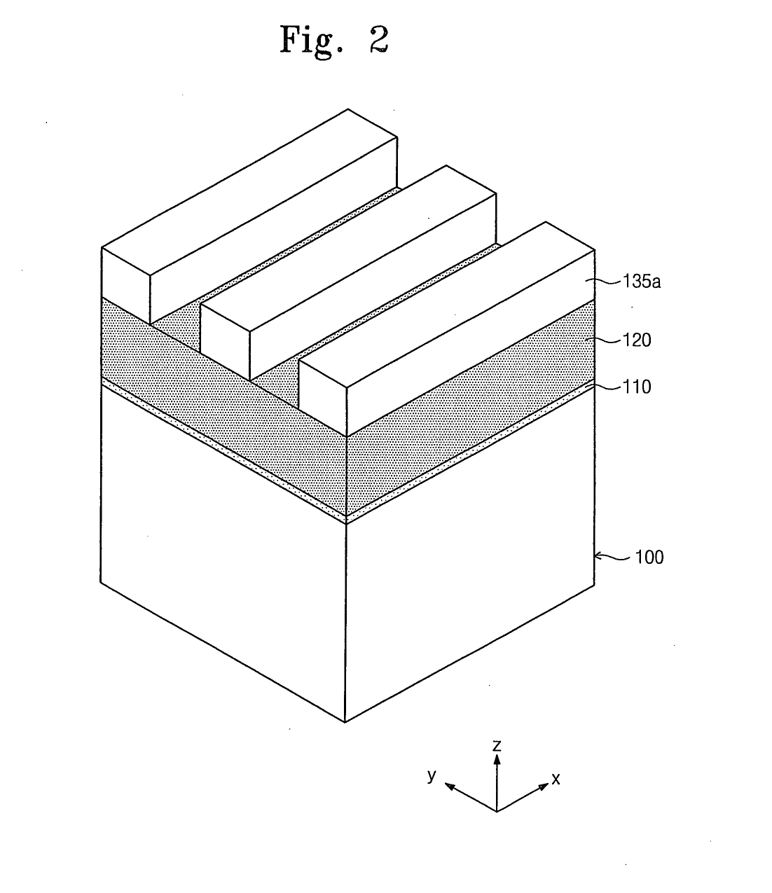

Referring to FIG. 2, a first hard mask pattern 135a may be formed by patterning the first hard mask layer 130. The hard mask pattern 135a may be formed with a line shape extending in a first direction in a plane view. The hard mask pattern 135a may be formed by forming an etch mask on the first hard mask layer 130 through an exposure process and then performing an etch process using the etch mask.

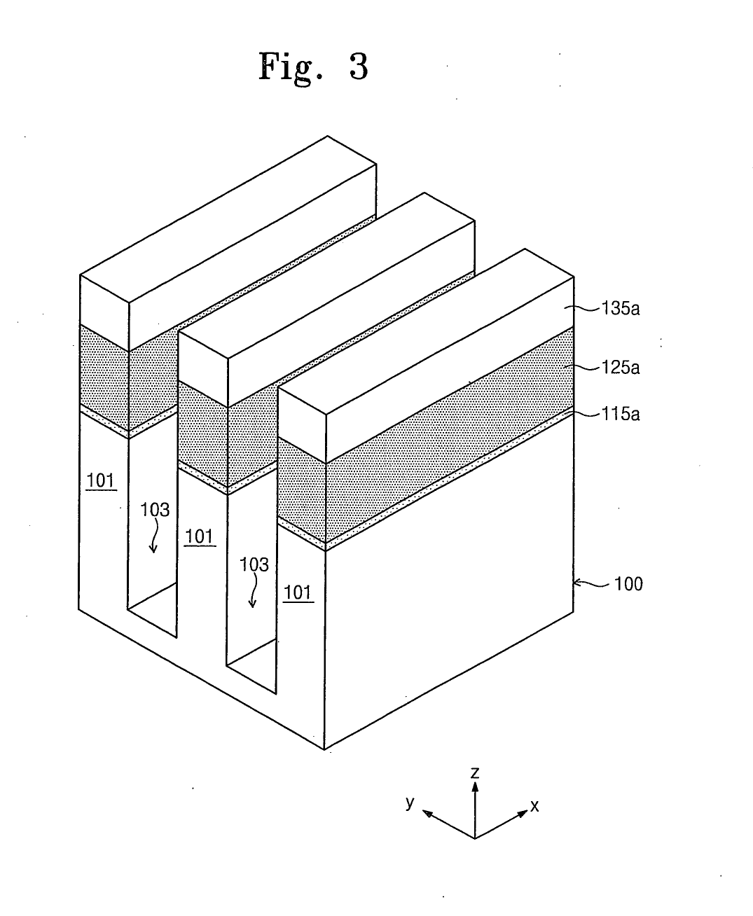

Referring to FIG. 3, the charge storage layer 120, the tunnel dielectric layer 110, and the substrate 100 may be sequentially etched by using the first hard mask pattern 135a as an etch mask. Accordingly, a trench 103 defining the active portions 101 and a preliminary charge storage pattern 125a and a tunnel dielectric pattern 115a that are sequentially stacked on each of the active portions 101 may be formed.

The etch process may include a dry etch process. According to an embodiment, the preliminary charge storage pattern 125a, the tunnel dielectric pattern 115a, and the trench 103 may be foamed through a single etch process. The preliminary charge storage pattern 125a, the tunnel dielectric pattern 115a, and the trench 103 may also be respectively formed through a plurality of etch processes.

The active portions 101 may be defined in the substrate 100 by the trench 103. The active portions 101 may have a line shape extending in the first direction in a plane view. The preliminary charge storage pattern 125a and the tunnel dielectric pattern 115a may be formed in plurality and each of the preliminary charge storage pattern 125a and the tunnel dielectric pattern 115a may be disposed on each of the active portions 101.

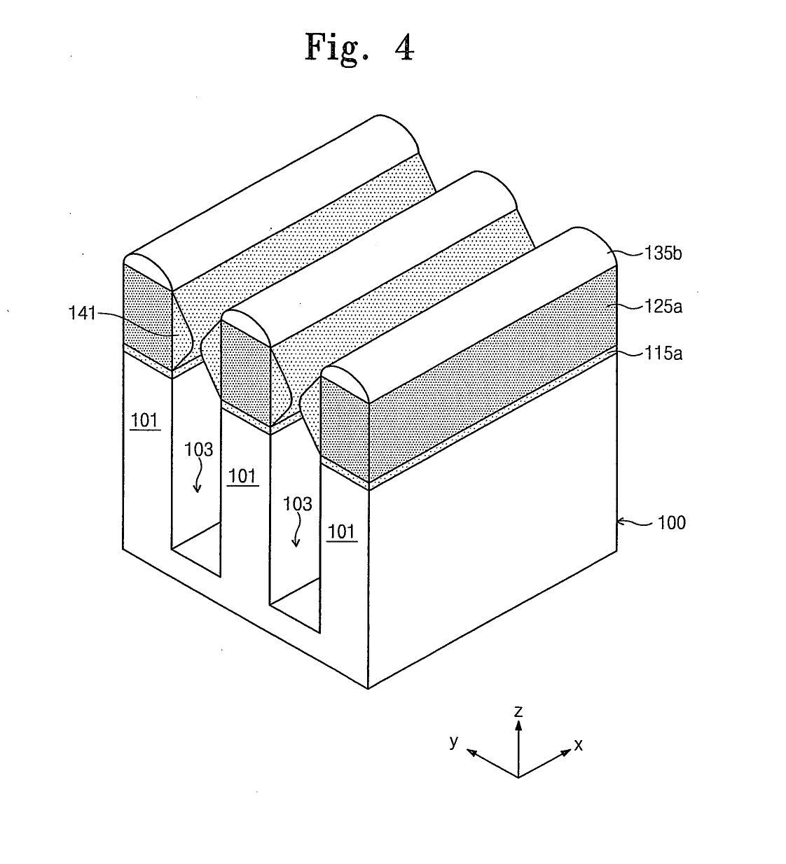

Referring to FIG. 4, protruding patterns 141 may be formed on sidewalls extending parallel in the first direction of the preliminary charge storage patterns 125a. One pair of protruding patterns 141 may be formed on the sidewalls of at least one pair of the preliminary charge storage patterns 125a facing each other. The pair of protruding patterns 141 may cover at least a portion of an upper end of the trench 103. The pair of protruding patterns 141 may have a tapered shape protruding from the sidewalls of the pair of protruding patterns 141 to face each other.

The protruding patterns 141 may be formed through a sputtering etch process using the first hard mask pattern 135a. The protruding patterns 141 may be formed by re-depositing etch particles (which are formed by colliding active gas ions to the etched first hard mask pattern 135b) on the sidewalls of the preliminary charge storage patterns 135a. The sputtering etch process may use a mixture gas formed of Ar/O or Ar/O/H. Additionally, the sputtering etch process may use process conditions such as a temperature from room temperature to about 500° C. and a pressure of about 0.5 Torr to about 10 Torr. Since the forming of the protruding patterns 141 use particles etched from the first hard mask pattern 135a, the thickness of the etched first hard mask pattern 135b may be reduced.

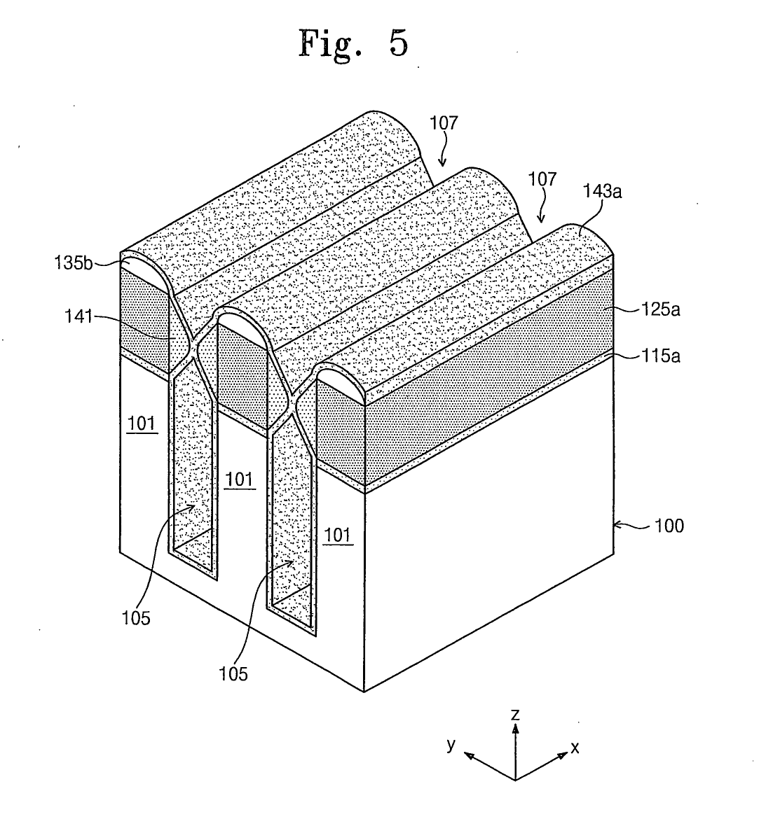

Referring to FIG. 5, a liner insulation layer 143a may be formed to conformally cover the surface of the etched first hard mask pattern 135b, the surfaces of the protruding patterns, and the inner surface of the trench 103. According to an example embodiment of the inventive concepts, the liner insulation layer 143a may conformally cover an entire inner surface of the trench 103. Accordingly, the first void 105 may have a form surrounded by the liner insulation layer 143a. Unlike in this example embodiment, the liner insulation layer 143a may cover a portion of the inner surface of the trench 103.

The liner insulation layer 143a may be formed through at least one of CVD, PVD, or ALD. For example, the liner insulation layer 143a may be formed through a CVD process under process conditions including a process temperature of about 700° C. to about 800° C. and a process pressure of about 3 Torr to about 10 Torr.

The liner insulation layer 143a may include at least one of oxide, nitride, or an oxide nitride. For example, the liner insulation layer 143a may be a high temperature oxidation.

The pair of protruding patterns 141 may be spaced from each other. According to an example embodiment of the inventive concepts, the liner insulation layer 143a may fill the pair of protruding patterns 141. That is, the upper portion of the trench 103 (see FIG. 4) may be completely covered by the liner insulation layer 143a formed on the surfaces of the pair of protruding patterns 141 facing each other. Accordingly, the first void 105 may be formed in the trench 103. Since the pair of protruding patterns 141 includes pointed portions facing each other, an upper portion of the first void 105 may be formed with a tapered shape toward the pair of protruding patterns 141. According to an example embodiment of the inventive concepts, the upper portion of the first void 105 may be formed disposed at a higher level than the upper surface of the substrate 100.

The first void 105 in the trench 103 may have a lower dielectric constant than an insulation material including oxide, nitride and/or oxide nitride. Accordingly, a parasite capacitance due to interface between the respectively adjacent active portions may be minimized or reduced. As a result, the reliability and electrical characteristics of a nonvolatile memory device may be improved.

Since the liner insulation layer 143a fills between the pair of protruding patterns 141 facing each other, a recessed region 107 may be formed on the protruding patterns 141. The inner surface of the recessed region 107 may be defined by the liner insulation layer 143a. The lowermost bottom surface of the recessed region 107 may have a shape pointed toward the pair of protruding patterns 141.

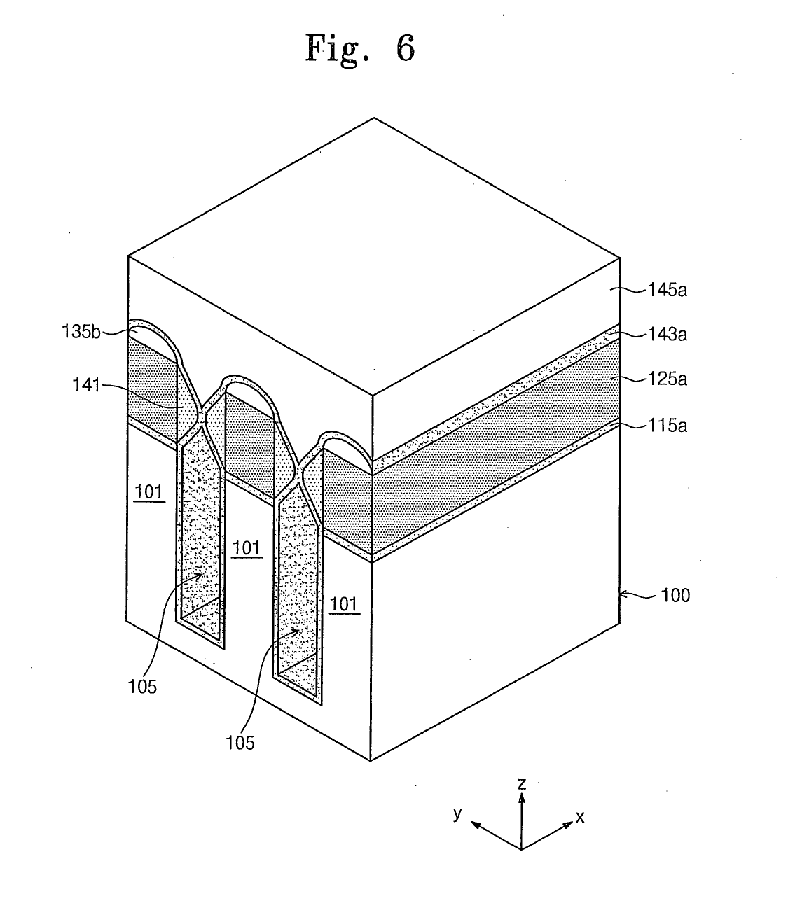

Referring to FIG. 6, a bulk insulation layer 145a may be formed on the substrate 100. The bulk insulation layer 145a may be formed to fill the recessed region 107. The bulk insulation layer 145a may be formed through at least one of CVD, PVD, or ALD. The bulk insulation layer 145a may include at least one of oxide, nitride, or oxide nitride. For example, the bulk insulation layer 145a may be Undoped Silicate Glass (USG).

According to an example embodiment of the inventive concepts, the protruding patterns 141 may be formed by re-depositing etch particles (that occur by performing a sputtering etch process on the first hard mask pattern 135a) on the sidewall of the preliminary charge storage pattern 125a. Accordingly, the upper portion of the trench 103 may be easily covered and also the first void 105 may be formed in the trench 103 with reproducibility.

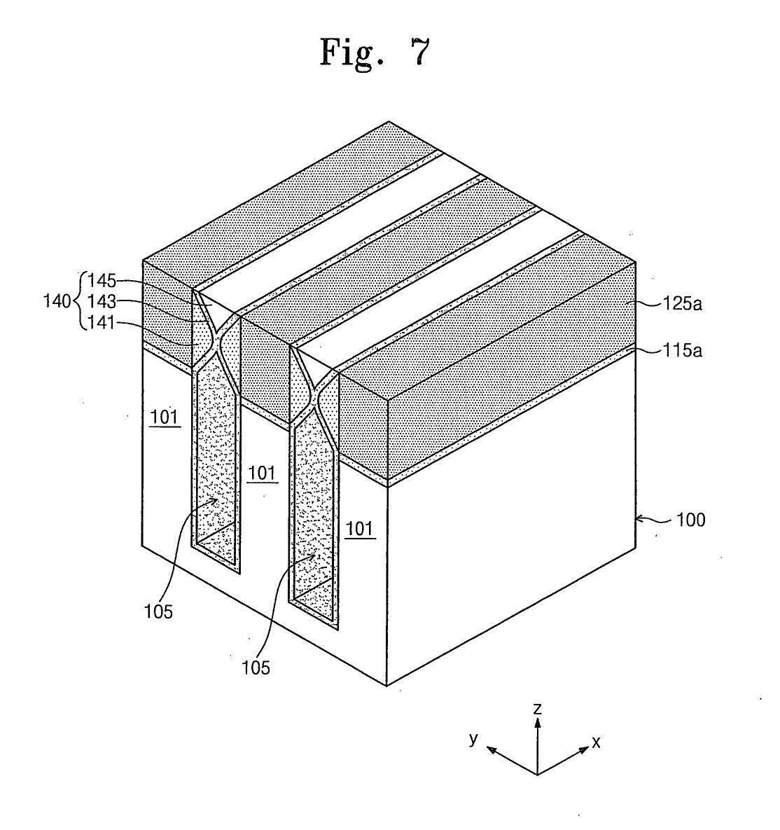

Referring to FIG. 7, a bulk insulation pattern 145 and a liner insulation pattern 143 may be formed by etching the bulk insulation layer 145a, the liner insulation layer 143a, and the etched first hard mask pattern 135b so that an upper surface of the preliminary charge storage pattern 125a is exposed. A level of the uppermost surfaces of the bulk insulation pattern 145 and the liner insulation pattern 143 may be identical to or lower than that of the upper surface of the preliminary charge storage pattern 125a.

The forming of the bulk insulation pattern 145 and the liner insulation pattern 143 may include at least one of a chemical mechanical polishing process, a dry etch process, or a wet etch process.

The liner insulation pattern 143 and the bulk insulation pattern 145 formed by an etch process for forming them and the pair of protruding patterns 141 may be included in a capping pattern 140. The capping pattern 140 may completely cover an upper portion of the trench 103 so that the first void 105 may be completely closed.

Unlike the above, according to an example embodiment, the pair of protruding patterns 141 may completely cover the upper portion of the trench 103. In this case, the first void 105 may be closed by the pair of protruding patterns 141. At this point, the liner insulation pattern 143 and/or the bulk insulation pattern 145 may be omitted.

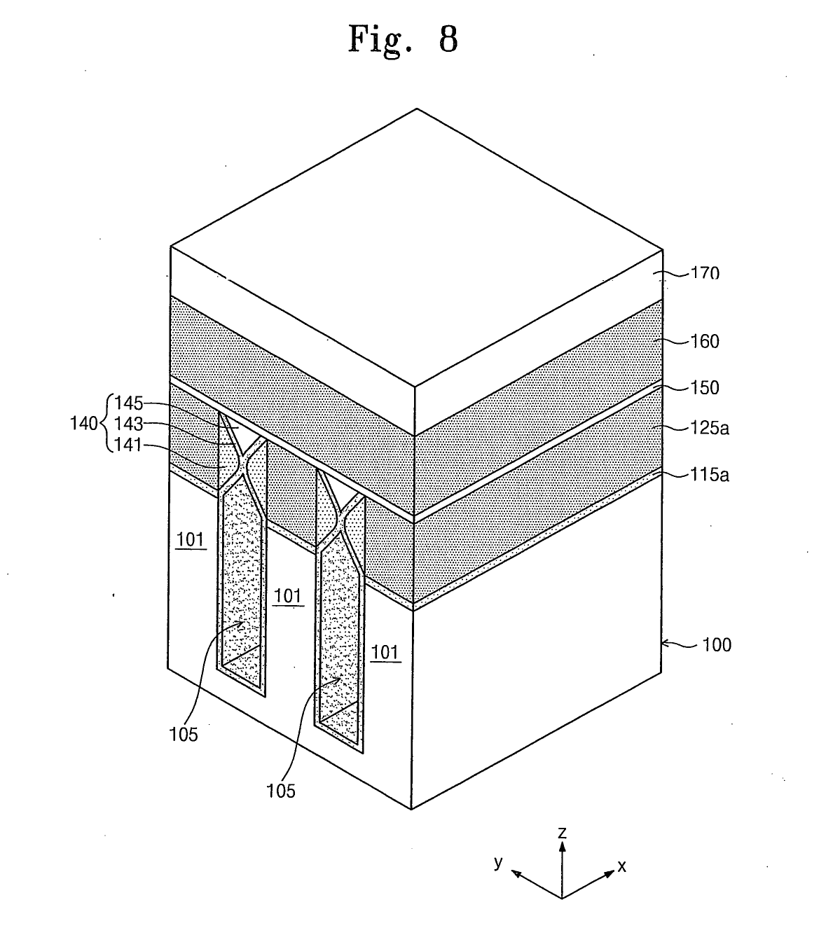

Referring to FIG. 8, a blocking dielectric layer 150, a control gate layer 160, and a second hard mask layer 170 may be sequentially formed on the substrate 100 having the capping pattern 140.

The blocking dielectric layer 150 may include a material having a higher dielectric constant than the tunnel dielectric layer 110. The blocking dielectric layer 150 may include at least one of a silicon oxide layer, a silicon nitride layer, a silicon oxynitride layer, or a high-k layer. The high-k layer may include at least one of a metal oxide layer, a metal nitride layer, or a metal oxynitride layer. For example, the high-k layer may include at least one of Hf, Zr, Al, Ta, La, Ce, or Pr.

The blocking dielectric layer 150 may be single-layered or multi-layered. The blocking dielectric layer 150 may be formed through at least one of CVD, PVD, or ALD. The control gate layer 160 may be formed on the blocking dielectric layer 150. The control gate layer 160 may be formed through at least one of CVD, PVD, or ALD.

The control gate layer 160 may be single-layered or multi-layered. The control gate layer 160 may include at least one of doped polysilicon, metal silicide, or a metal nitride layer. The metal silicide may include a tungsten silicide layer, a titanium silicide layer, a cobalt silicide layer, and a tantalum silicide layer. The metal nitride layer may include titanium nitride or tantalum nitride.

The second hard mask layer 170 may be formed on the control gate layer 160. The second hard mask layer 170 may be the same as the first hard mask layer 130 described with reference to FIG. 1. Accordingly, the second hard mask layer 170 may be formed using the same method as the first hard mask layer 130 and may include the same material as the first hard mask layer 130.

Unlike this example embodiment, the second hard mask layer 170 may be formed through spin coating. In this case, the second hard mask layer 170 may be formed of a polymeric material including silicon and carbon. For example, the second hard mask layer 170 may be a Spin On Hardmask (SOH) layer.

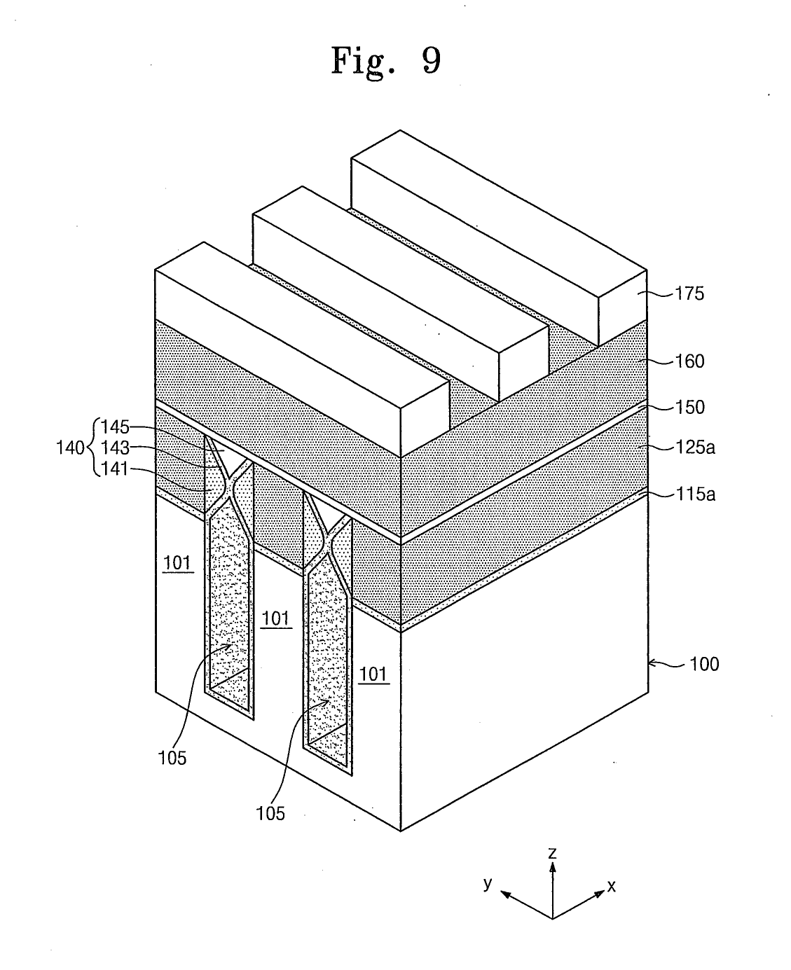

Referring to FIG. 9, a second hard mask pattern 175 may be formed by patterning the second hard mask layer 170. The second hard mask pattern 175 may be formed with a line shape extending in a second direction intersecting the first direction in a plane view. The second hard mask pattern 175 may be formed through the same method as the first hard mask pattern 135a. A portion of the upper surface of the control gate layer 160 may be exposed due to the forming of the second hard mask pattern 175.

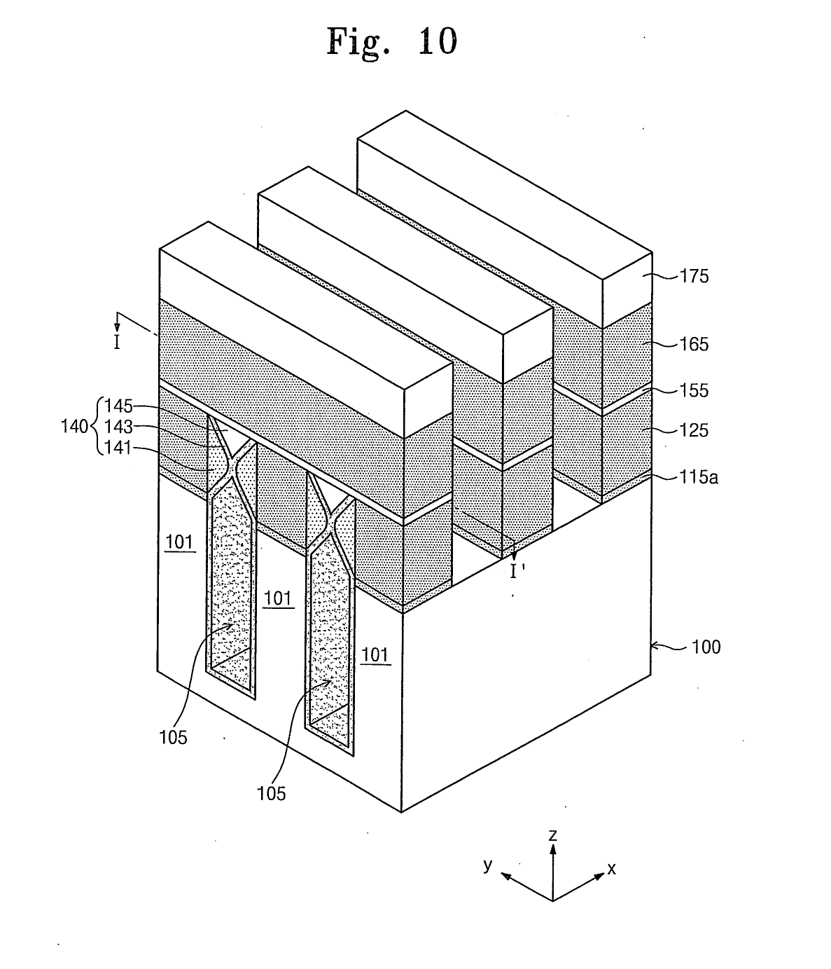

Referring to FIG. 10, the control gate layer 160, the blocking dielectric layer 150, and the preliminary charge storage pattern 125a may be continuously etched using the second hard mask pattern 175 as an etching mask. Accordingly, a sequentially-stacked charge storage pattern 125, blocking dielectric pattern 155, and control gate electrode 165 may be fanned. According to an example embodiment, etching of the control gate layer 160, the blocking dielectric layer 150, and the preliminary charge storage pattern 125a may be performed by a dry etch process. Unlike this example embodiment, the charge storage pattern 125, the blocking dielectric pattern 155, and the control gate electrode 165 may be formed through a plurality of dry etch processes.

According to an example embodiment, the etch process may include etching the tunnel dielectric pattern 115a. In this case, a portion of the upper surfaces of the active portions 101 may be exposed.

A plurality of charge storage patterns 125 may be provided on the active portions 101. The charge storage patterns 125 may be two-dimensionally arranged according to rows and columns. The rows may extend in parallel to the first direction and the columns may extend in parallel to the second direction. The charge storage patterns 125 may include first sidewalls parallel to the first direction and second sidewalls parallel to the second direction.

The blocking dielectric pattern 155 and the control gate electrode 165 may be provided in plurality. The blocking dielectric pattern 155 and the control gate electrode 165 may be disposed on the charge storage patterns 125 included in each of the columns parallel to the second direction. Accordingly, each of the blocking dielectric pattern 155 and the control gate electrode 165 may extend parallel to the second direction.

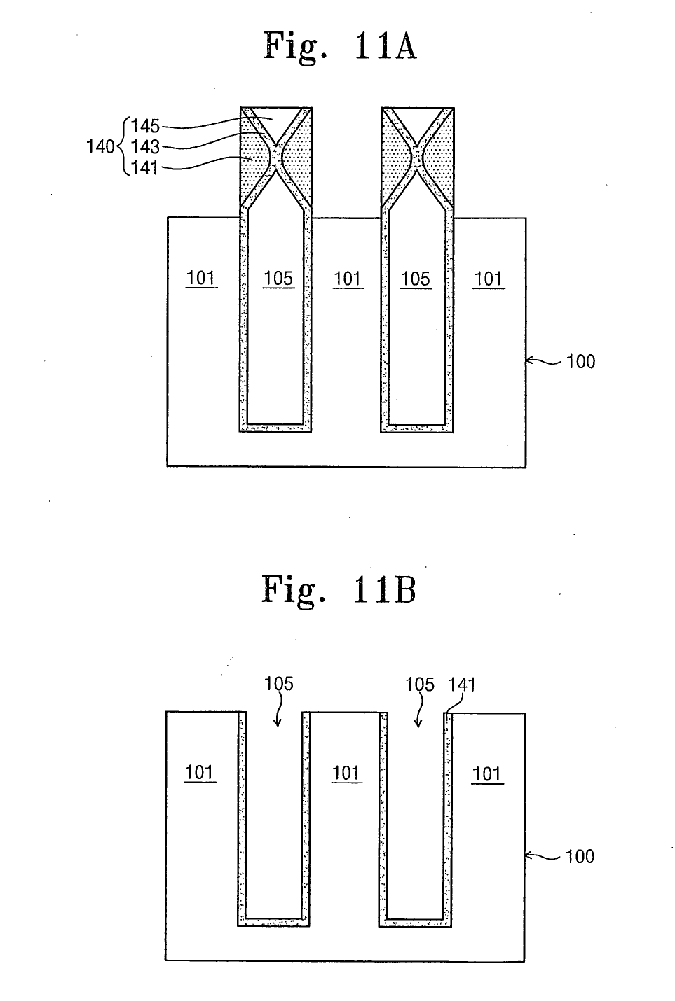

The forming of the charge storage pattern 125, the blocking dielectric pattern 155, and the control gate electrode 165 may be performed through a dry etch process using a process condition having an etch selectivity with respect to the capping pattern 140. In this case, as shown in FIG. 11A, a portion of the capping pattern 140 may be exposed between the control gate electrodes.

Unlike this example embodiment, as shown in FIG. 11B, a portion of the first void 105 may be opened by etching a portion of the exposed capping pattern 140 between the control gate electrodes 165. In this case, the liner insulation pattern 143 that is formed conformally on the inner surface of the trench 103 may be exposed.

By an etch process for forming the charge storage pattern 125, a portion of the exposed capping pattern 140 between the control gate electrodes 165 may be substantially and simultaneously etched together with the preliminary charge storage pattern 125a. Or, a portion of the exposed capping pattern 140 between the control gate electrodes 165 may be etched after the charge storage pattern 125 is formed.

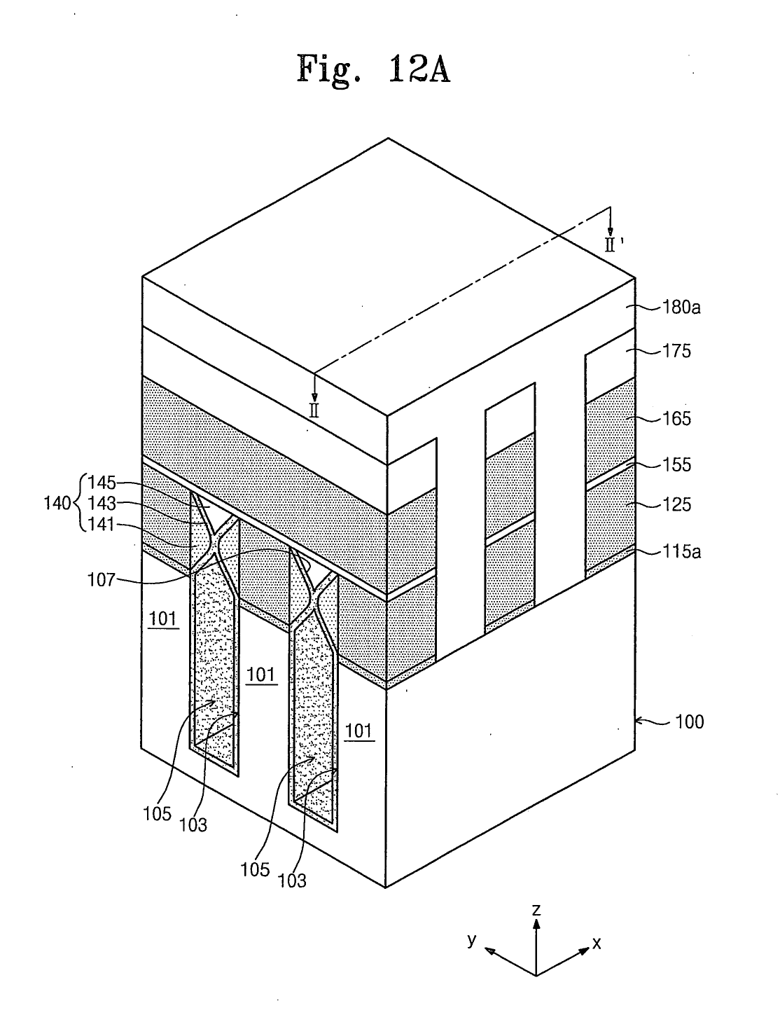

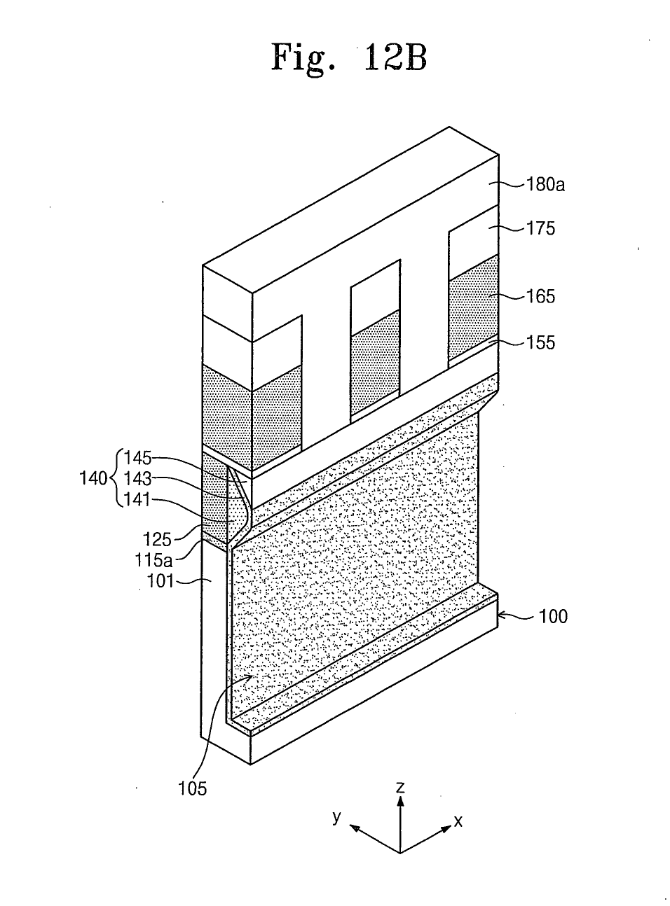

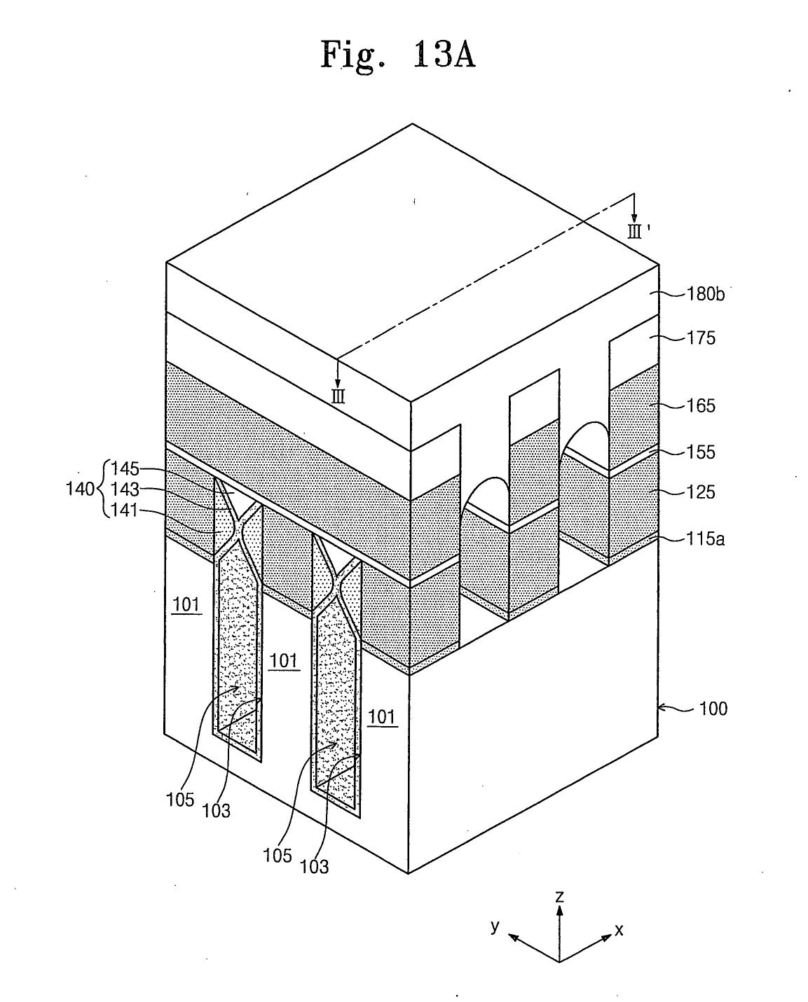

Interlayer insulation layers 180a and 180b may be formed on the control gate electrodes 165. According to an example embodiment, as shown in FIGS. 12A and 12B, the interlayer insulation layer 180a may completely fill a space between the control gate electrodes 165. Accordingly, the lowermost surface of the interlayer insulation layer 180a may contact the upper surface of the capping pattern 140.

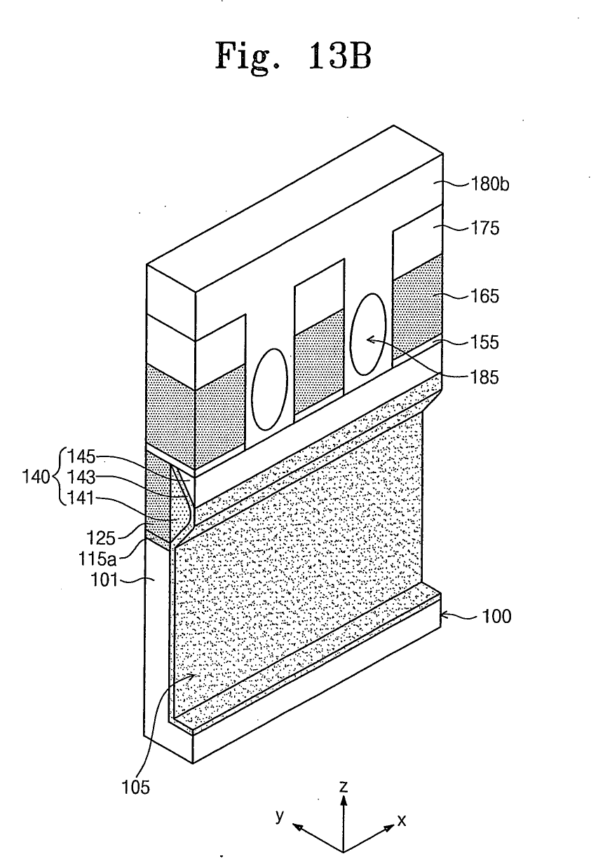

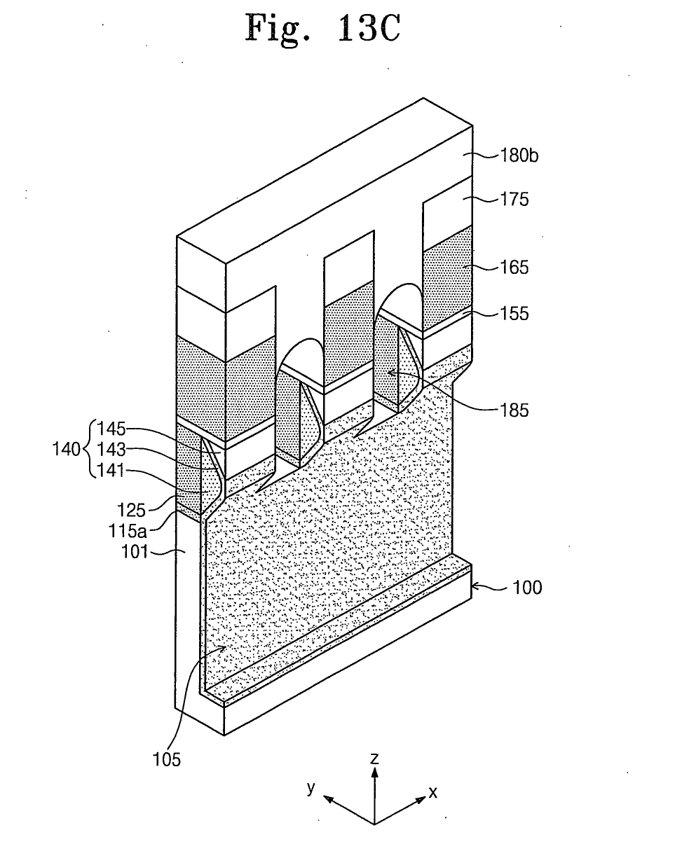

Unlike this example embodiment, as shown in FIGS. 13A, 13B, and 13C, the interlayer insulation layer 180b may fill at least a portion of the space between the control gate electrodes 165. Accordingly, at least a portion of the space between the control gate electrodes 165 may not be filled. In this case, a second void 185 may be formed between the control gate electrodes 165. At least a lower portion of the second void 185 may be disposed at a lower level than the upper surface of the charge storage pattern 125.

Referring to FIG. 13B, the capping pattern 140 may have a line extending in the first direction in a plane view. Accordingly, the second void 185 and the first void 105 may be separated from each other by the capping pattern 140. In this case, the second void 185 may have a line shape extending in the second direction in a plane view.

Unlike this example embodiment, referring to FIG. 13C, when a portion of the first void 105 is opened by etching a portion of the exposed capping pattern 140 between the control gate electrodes 165, the first void 105 may be connected to the second void 185.

(Nonvolatile Memory Device)

Hereinafter, a nonvolatile memory device according to example embodiments of the inventive concepts will be described in more detail with reference to the drawings. FIG. 12A is a perspective view of a nonvolatile memory device according to an example embodiment of the inventive concepts. FIG. 12B is a perspective view taken along the line II-II′ of FIG. 12A.

Referring to FIGS. 12A and 12B, a trench defining active portions 101 may be disposed in a substrate 100. The trench 103 may have a line shape extending in a first direction in a plane view. The substrate 100 may include semiconductor material. For example, the substrate 100 may include at least one of silicon or germanium.

A charge storage pattern 125 may be disposed on the substrate 100. A plurality of charge storage patterns 125 may be provided on each of the active portions 101. Accordingly, the charge storage patterns 125 may be two-dimensionally arranged along rows and columns. The rows may extend parallel to the first direction and the columns may extend parallel to a second direction intersecting the first direction.

The charge storage patterns 125 may include first sidewalls parallel to the first direction and second sidewalls parallel to the second direction. Accordingly, the first sidewalls of the charge storage patterns 125 may be aligned to one side of the trench 103.

The charge storage patterns 125 may include doped polysilicon or undoped polysilicon. Unlike this example embodiment, the charge storage patterns 125 may include a charge trap site for storing charges. For example, the charge storage patterns 125 may include at least one of silicon nitride, metal nitride, metal oxide, metal silicon oxide, metal silicon oxide, or nano dots.

A tunnel dielectric pattern 115a may be disposed between each of the active portions 101 of the substrate 100 and the charges storage patterns 125. The tunnel dielectric pattern 115a may be single-layered or multi-layered. The tunnel dielectric pattern 115a may include at least one of oxide, nitride, metal oxide, or oxide nitride.

A capping pattern 140 may be disposed between the first sidewalls of one pair of charge storage patterns 125 facing each other. As shown in FIG. 12B, the capping pattern 140 may define the first void 105 disposed in the trench 103. The capping pattern 140 may have a line shape extending in the first direction in a plane view.

The capping pattern 140 may include one pair of protruding patterns 141. The pair of protruding patterns 141 may be disposed to face each other on the first sidewalls of the charge storage patterns 125 facing each other. Accordingly, the pair of protruding patterns 141 may cover at least an upper portion of the trench 103. The pair of protruding patterns 141 may have a tapered shape facing each other.

Although not shown in the drawings, the protruding patterns 141 may be formed by re-depositing etch particles (that occur by performing a sputtering etch process on a hard mask pattern used for forming the trench 103) on the first sidewalls of the charge storage patterns 125. Accordingly, the protruding patterns 141 may include etch particles occurring by a sputtering etch process. The protruding patterns 141 may include at least one of oxide, nitride, or oxide nitride.

According to an embodiment, the pair of protruding patterns 141 may be spaced from each other. Accordingly, the capping pattern 140 may further a liner insulation pattern 143 and a bulk insulation pattern 145 filling between the pair of protruding patterns 141.

The liner insulation pattern 143 may be disposed to conformally cover the surfaces of the protruding patterns 141 and the inner surface of trench 103, thereby filling between the pair of protruding patterns 141. The liner insulation pattern 143 may include at least one of oxide, nitride, or oxide nitride. For example, the liner insulation pattern 143 may be a high temperature oxidation.

Portions of the liner insulation patterns 143 disposed between the pair of protruding patterns 141 facing each other may be connected to each other to completely cover the upper portion of the trench 103. Accordingly, a first void 105 may be defined in the trench 103 by the pair of protruding patterns 141 and the liner insulation pattern 143.

The first void 105 may have a line shape extending in the first direction in a plane view. The connected portion of the liner insulation pattern 143 may be a portion that covers tapered portions of the pair of protruding patterns 141. Accordingly, an upper portion of the first void 105 may have a tapered shape pointed toward the pair of protruding patterns 141. According to an example embodiment, an upper portion of the first void 105 may be positioned at a higher level than an upper surface of the substrate 100.

The first void 105 in the trench 103 may have a lower dielectric constant than an insulation material including an oxide, a nitride and/or an oxide nitride. Accordingly, a parasite capacitance due to interference between the respectively adjacent active portions may be minimized or reduced. As a result, the reliability and electrical characteristics of a nonvolatile memory device according to an example embodiment of the inventive concepts may be improved.

According to an example embodiment, the liner insulation pattern 143 may conformally cover an entire inner surface of the trench 103. Accordingly, the first void 105 may have a shape surrounding the liner insulation pattern 143.

Unlike in the drawings, the liner insulation pattern 143 may cover a portion of the inner surface of the trench 103. In this case, the first void 105 may contact a portion of the inner surface of the trench 103.

Since the pair of protruding patterns 141 has a portion pointed to each other, a recessed region 107 may be disposed on the protruding patterns 141. The bulk insulation pattern 145 may be disposed to fill the recessed region 107. The bulk insulation pattern 145 may include at least one of oxide, nitride, or an oxide nitride. For example, the bulk insulation pattern 145 may be USG (Undoped Silicate Glass).

According to an example embodiment, unlike the drawings, the pair of protruding patterns 141 may completely cover the upper portion of the trench 103. In this case, the tapered portions of the pair of protruding patterns 141 may be connected to each other. Accordingly, a first void 105 may be defined in the trench 103 by the pair of protruding patterns 141. According to this example embodiment, the liner insulation pattern 143 and/or the bulk insulation pattern 145 may be omitted.

A control gate electrode 165 may be disposed on the substrate 100 having the capping pattern 140. The control gate electrode 165 may be single-layered or multi-layered. The control gate electrode 165 may include at least one of doped polysilicon, metal, metal silicide, or a metal nitride layer.

A plurality of the control gate electrodes 165 may be provided. Each of the control gate electrodes 165 may be disposed on the charge storage patterns 125 including in each column. Accordingly, the control gate electrode 165 may have a line shape extending in the second direction in a plane view.

A blocking dielectric pattern 155 may be interposed between the charge storage pattern 125 and the control gate electrode 165 in each column. The blocking dielectric pattern 155 may be single-layered or multi-layered. The blocking dielectric pattern 155 may include a material having a higher dielectric constant than the tunnel dielectric pattern 155a. The blocking dielectric pattern 155 may include at least one of a silicon oxide layer a silicon nitride layer, a silicon oxynitride layer, or a high-k layer. The high-k layer may include at least one of a metal oxide layer, a metal nitride layer, or a metal oxynitride layer. For example, the high-k layer may include at least one of Hf, Zr, Al, Ta, La, Ce, or Pr.

A second hard mask pattern 175 may be formed on a portion of the upper surface of the control gate electrode 165 with a line shape extending in a second direction intersecting the first direction in a plane view. An interlayer insulation layer 180a may also be disposed on the control gate electrodes 165. As shown in FIG. 12B, the interlayer insulation layer 180a may completely fill a space between respectively adjacent control gate electrodes. At this point, the capping pattern 140 may have a line shape extending in a first direction in a plane view. The first void 105 may be completely closed by the capping pattern 140. Accordingly, the first void 105 may contact a portion of the capping pattern 140 between the control gate electrodes 165 of the interlayer insulation layer 180a. The interlayer insulation layer 180a may include insulation material. For example, the interlayer insulation layer 180a may include silicon oxide, silicon nitride, or silicon oxide nitride.

FIG. 13A is a perspective view illustrating a nonvolatile memory device according to another modification of the example embodiment of the inventive concepts. FIGS. 13B and 13C are perspective views taken along the line of FIG. 13A. Other configurations of the nonvolatile memory device according to this embodiment may be identical to those according to the above embodiment. The same configurations will not be described.

Referring to FIGS. 13A and 13B, an interlayer insulation layer 180b may be disposed on the control gate electrodes 165. The interlayer insulation layer 180b may fill at least a portion of a space between the control gate electrodes 165. Accordingly, at least a portion of the space between the control gate electrodes 165 may not be filled. In this case, a second void 185 may be disposed between the control gate electrodes 165 as shown in FIG. 13B. At least a portion of the bottom of the second void may be disposed at a lower level than the upper surface of the charge storage pattern 125.

The interlayer insulation layer 180a may include insulation material. For example, the interlayer insulation layer 180a may include silicon oxide, silicon nitride, or silicon oxide nitride.

Referring to FIG. 13B, the capping pattern 140 may have a line shape extending in the first direction in a plane view. Accordingly, the second void 185 and the first void 105 may be separated from each other by the capping pattern 140. In this case, the second void 185 may have a line shape extending in the second direction in a plane view.

Unlike this example embodiment, referring to FIG. 13C, when a portion of the capping pattern 140 exposed between the control gate electrodes 165 is removed and thus a portion of the first void 105 is opened, the first void 105 may be connected to the second void 185.

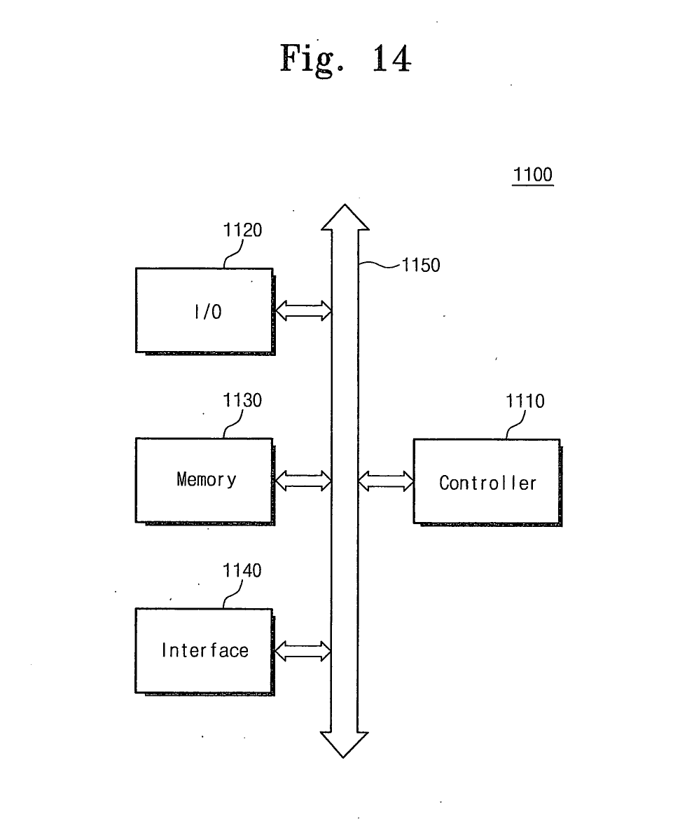

FIG. 14 is a block diagram illustrating one example of an electronic system including a nonvolatile memory device based on the technical ideas of example embodiments of the inventive concepts. Referring to FIG. 14, the electronic system 1100 includes a controller 1110, an input/output device (or I/O) 1120, a memory device 1130, an interface 1140, and a bus 1150. The controller 1110, the input/output device 1120, the memory device 1130, and/or the interface 1140 may be combined through the bus 1150. The bus 1150 corresponds to a path through which data transfers.

The controller 1110 may include at least one micro processor, digital signal processor, micro controller, or other processors similar thereto. The input/output device 1120 may include a keypad, a keyboard, and a display device. The memory device 1130 may store data and/or commands. The memory device 1130 may include at least one of the semiconductor devices disclosed in the example embodiments of the inventive concepts. Moreover, the memory device 1130 may further include different forms of a semiconductor memory device (e.g., a DRAM device and/or an SRAM device). The interface 1140 may serve to transmit or receiving data through a communication network. The interface 1140 may have a wire or wireless form. For example, the interface 1140 may include an antenna or a wire/wireless transceiver. Although not shown in the drawings, the electronic system 1100 may further include a high-speed DRAM and/or SRAM as an operating memory for improving an operation of the controller 1110.

The electronic system 1100 may be applied to a PDA, a portable computer, a web tablet, a wireless phone, a mobile phone, a digital music player, a memory card, or all devices for transmitting and receiving information via a wireless environment.

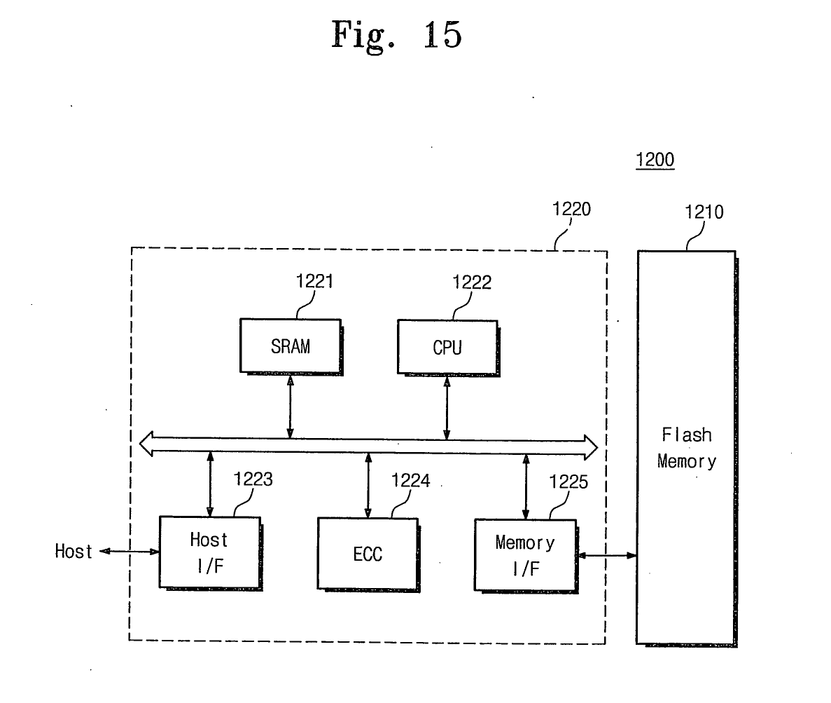

FIG. 15 is a block diagram illustrating one example of a memory card with a semiconductor device based on the technical ideas of example embodiments of the inventive concepts.

Referring to FIG. 15, the memory card 1200 includes a memory device 1210. The memory device 1210 may include at least one of the semiconductor devices disclosed in example embodiments of the inventive concepts. Furthermore, the memory device 1210 may further include different forms of a semiconductor memory device (e.g., a DRAM device and/or an SRAM device). The memory card 1200 may include a memory controller 1220 controlling data exchanges between a host and the memory device 1210.

The memory controller 1220 may include a central processing unit (CPU) 1222 controlling general operations of a memory card. Additionally, the memory controller 1220 may include an SRAM 1221 used as an operating memory of the CPU 1222. Furthermore, the memory controller 1200 may further include a host interface 1223 and a memory interface 1225. The host interface 1223 may include a data exchange protocol between the memory card 1200 and the host. The memory interface 1225 may connect the memory controller 1220 to the memory device 1210. Furthermore, the memory controller 1220 may further include an error correction code block (ECC) 1224. The ECC 1224 detects and corrects errors in data read from the memory device 1210. Although not shown in the drawings, the memory card 1200 may further include a ROM device storing code data to interface with a host. The memory card 1200 may be used as a portable data storage card. Unlike this example embodiment, the memory card 1200 may be realized with a solid state disk (SSD) that may replace a hard disk of a computer system.

According to the above-mentioned memory device, a void is formed in a trench defining active portions in the substrate. Accordingly, reliability and electrical characteristics of a nonvolatile memory device can be improved by minimizing a parasite capacitance between respectively adjacent active portions. Moreover, since the void is formed through a sputtering etch process that uses a hard mask pattern used for forming the trench, the void can be more easily formed in the substrate and can be formed with reproducibility.

The above-disclosed subject matter is to be considered illustrative and not restrictive, and the appended claims are intended to cover all such modifications, enhancements, and other example embodiments, which fall within the true spirit and scope of example embodiments of the inventive concepts. Thus, to the maximum extent allowed by law, the scope of the inventive concepts is to be determined by the broadest permissible interpretation of the following claims and their equivalents, and shall not be restricted or limited by the foregoing detailed description.

1-10. (canceled)

11. A nonvolatile memory device comprising:
active portions defined by a trench in a substrate, the active portions extending parallel to a first direction;
charge storage patterns disposed on the active portions, the charge storage patterns having first sidewalls parallel to the first direction and second sidewalls parallel to a second direction intersecting the first direction;
a tunnel dielectric pattern interposed between the active portions and the charge storage pattern;
a capping pattern disposed between the first sidewalls of the charge storage patterns and covering an upper portion of the trench to define a first void in a portion of the trench, the capping pattern including laterally extending protruding patterns re-deposited by a sputtering etch process;
a control gate electrode disposed on the charge storage patterns; and
blocking dielectric patterns interposed between the charge storage patterns and the control gate electrode.

12. The nonvolatile memory device of claim 11, wherein
the control gate electrode is a plurality of control gate electrodes laterally extending in the second direction;
the charge storage pattern is a plurality of charge storage patterns two-dimensionally arranged along rows and columns; and
each of the control gate electrodes is disposed on an upper surface of the charge storage patterns in each of the columns parallel to the second direction.

13. The nonvolatile memory device of claim 11, further comprising:
an interlayer insulation layer on the plurality of control gate electrodes, the interlayer insulation layer including a second void disposed between the plurality of control gate electrodes.

14. The nonvolatile memory device of claim 13, wherein the first void and the second void are connected to each other.

15. The nonvolatile memory device of claim 13, wherein the first void and the second void are separated from each other by the capping pattern.

16-20. (canceled)

21. A nonvolatile memory device comprising:
active portions defined by a trench in a substrate, the active portions extending parallel to a first direction and the trench including a first opening;
charge storage patterns disposed on the active portions, the charge storage patterns having first sidewalls parallel to the first direction and second sidewalls parallel to a second direction intersecting the first direction; and
a capping pattern disposed between the first sidewalls of the charge storage patterns and covering an upper surface of the trench, the capping pattern including protruding patterns.

22. The nonvolatile memory device of claim 21, further comprising:
a tunnel dielectric pattern interposed between the active portions and the charge storage pattern;
a plurality of control gate electrodes disposed on upper surfaces of the charge storage patterns; and
blocking dielectric patterns interposed between the charge storage patterns and the plurality of control gate electrodes, the plurality of control gate electrodes laterally extending in the second direction.

23. The nonvolatile memory device of claim 22, further comprising:
an interlayer insulation layer on the plurality of control gate electrodes, the interlayer insulation layer including a second opening disposed between plurality of control gate electrodes.

24. The nonvolatile memory device of claim 23, wherein the first opening and the second opening are connected to each other.

25. The nonvolatile memory device of claim 23, wherein the first opening and the second opening are separated from each other by the capping pattern.
